(19) United States
(12) Patent Application Publication
(10) Pub. No.: US 2010/0314608 A1
(43) Pub. Date: Dec. 16, 2010

(54) PHOTODETECTORS

(75) Inventor: Doyeol AHN, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: UNIVERSITY OF SEOUL INDUSTRY COOPERATION FOUNDATION, Seoul (KR)

(21) Appl. No.: 12/198,816

(22) Filed: Aug. 26, 2008

(51) Int. Cl. H01L 31/0352

(52) U.S. Cl. 257/14; 257/21; 257/E31.032

(57) ABSTRACT

Implementations of quantum well photodetectors are provided.

### BACKGROUND

Photodetectors (or photosensors) may be sensors capable of detecting light or other electromagnetic energy using interband transition of electrons in a quantum well to detect a photon with a specific energy level (i.e., energy difference between subbands in a quantum well). When a photon having energy more than the subband energy difference enters a quantum well of a photodetector, electrons in the quantum well may become excited, i.e., transition to an upper subband and “tunnel the barrier,” and such electron transition causes an electric current through the photodetector.

A photon with a specific energy may be detected by measuring or monitoring such electric current through the photodetector. For example, a photon with a frequency of several Terra Hertz (THz) has an energy value of several to tens of meV. To detect a photon with several THz frequency, it may be necessary to form a quantum well with an inter subband energy difference of several to tens of meV. However, in typical semiconductor materials, inter subband energy differences in quantum wells tend to be hundreds to thousands of meV.

### SUMMARY

Various embodiments of photodetectors capable of detecting a photon with a frequency on the order of several THz are disclosed. In one embodiment by way of non-limiting example, a photodetector includes a quantum structure having a well layer, wherein the well layer has at least one valley split state of electrons such that transition of the electrons in the at least one valley split state corresponds to a photon with a predetermined energy.

The Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a schematic diagram showing an illustrative embodiment of a photodetector.

FIG. 2 an illustrative embodiment of a mechanism of valley splitting in a silicon quantum well of the photodetector shown in FIG. 1.

FIG. 3 is an illustrative embodiment of a relationship between valley split energy of a subband and well width of a photodetector.

FIG. 4 is an illustrative embodiment of a relationship between valley split energy of multiple subbands and well width of a photodetector.

FIG. 5 is an illustrative embodiment of a relationship between multiple subband energy with valley split and external electric field of a photodetector.

FIGS. 6A to 6C illustrate relationships among valley split energy, well width and external electric field of a photodetector.

FIG. 7 is a schematic diagram showing an illustrative embodiment of a photodetecting circuit.

FIG. 8 is an illustrative embodiment of an energy diagram showing a mechanism of photodetection.

FIG. 9 is a schematic diagram showing another illustrative embodiment of a photodetector.

FIG. 10 is an illustrative embodiment of an energy diagram showing a mechanism of photodetection in FIG. 9.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure, as generally described herein, and illustrated in the Figures, may be arranged, substituted, combined, and designed in a wide variety of different configurations, all of which are explicitly contemplated and make part of this disclosure.

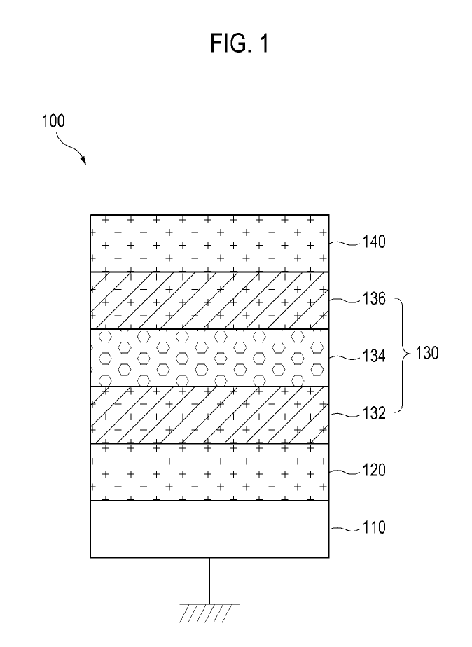

FIG. 1 shows an illustrative embodiment of a photodetector 100. As depicted, photodetector 100 may have a laminated structure in which a substrate 110, a first doped layer 120, a quantum structure 130, and a second doped layer 140 are sequentially stacked. Quantum structure 130 may include a first barrier layer 132, a second barrier layer 136, and a well layer 134 interposed between first barrier layer 132 and second barrier layer 136. Although quantum structure 130 is depicted as including only one well layer 134 in FIG. 1, there may be more than one well layer in other embodiments. By way of example, but not limitation, quantum structure 130 may have two or more well layers, such as well layer 134, and corresponding multiple barrier layers.

Substrate 110 may include semiconductor substrates suitable for the growth of other layers thereon (i.e., first doped layer 120, quantum structure 130 and second doped layer 140). For example, substrate 110 may include Si, SiO₂ or SiGe substrate, etc., when quantum structure 130 includes Si. First doped layer 120 may include highly doped n-type semiconductor materials. To form first doped layer 120, an intrinsic layer may be grown over substrate 110 and then the intrinsic layer may be doped with an n-type impurity such as Si, Ge, Sn or Te. Second doped layer 140 may include highly doped p-type semiconductor material. To form second doped layer 140, an intrinsic layer may be grown over quantum structure 130 and then the intrinsic layer may be doped with p-type impurity such as Zn, Mg, Ca or Be. The types of first and second doped layers 120, 140 may be changed; by way of example, but not limitation, first doped layer 120 may be doped with a p-type impurity, and second doped layer 140 doped with an n-type impurity.

Layers 120, 132, 134, 136, 140 in photodetector 100 may be grown by one of molecular bean epitaxy (MBE), metalorganic chemical vapor deposition (MOCVD) or numerous other growth methods as appropriate. Although not shown in FIG. 1, photodetector 100 may further include a capping layer or a contact layer for contacting electrodes to apply electric fields thereto.

Well layer 134 in quantum structure 130 may be formed from materials having at least one intervalley state with a predetermined energy difference under certain conditions. In the present disclosure, an “intervalley state” corresponds to a phenomenon in which the wave functions of electrons in a quantum well interact with each other yield split energy states. Such phenomena may be also called “valley splitting” or “intervalley interaction.”

Well layer 134 may include silicon, silicon oxide, silicon germanium, or a variety of materials capable of forming intervalley states. Intervalley states may have energy differences ranging from several meV to tens of meV, corresponding to photon energies of several THz frequency determined from the following Equation 1.

E=hv (Equation 1)

where E is energy of a photon, h is Plank's coefficient and v is frequency of the photon.

The energy differences of intervalley states may be related to the thickness (width) of well layer 134. By way of example, but not limitation, the thickness of well layer 134 may range from approximately 2 to 10 nm. Intervalley state energy differences may also be related to the strength of electric fields applied across photodetector 100. For example, an electric field across photodetector 100 may have a range of approximately 0 to 10×10⁷V/m. When the electric field across photodetector 100 is approximately 10×10⁷V/m the intervalley state energy differences may have a range of 5 meV to 30 meV.

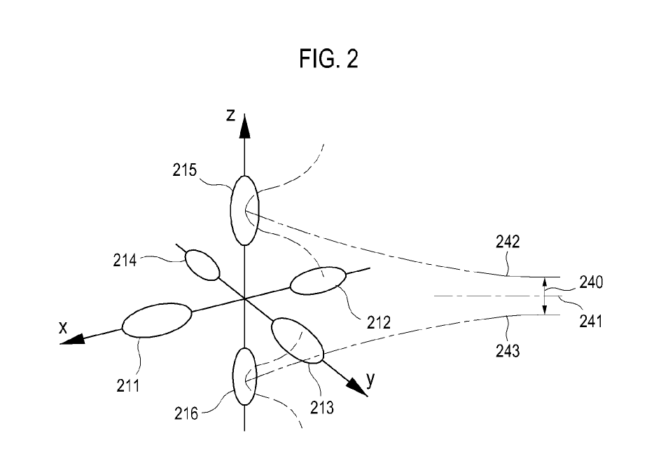

FIG. 2 shows an illustrative embodiment of a mechanism of valley splitting in a silicon quantum well of a photodetector. The x, y and z axes represent 3-dimensional directions in a silicon crystal. As depicted, the silicon crystal has the lowest conduction band (i.e., ground state), corresponding to six equivalent minima of ellipsoidal shape called valleys 211 to 216. Valleys 211 to 216 represent clouds of electrons or distributions of electrons. For illustration purposes, but not limitation, it is assumed that the z-direction lies along silicon <001> surface, and the ground state has only two degenerate valleys 215 and 216. In the absence of intervalley interaction, the ground state wave function may be obtained from linear combination of two wave functions of valleys 215, 216 to form a ground state 241. With intervalley interaction, two wave functions of valleys 215, 216 interact to split ground state 241 into two valley states 242 and 243. When a photon with energy having an energy corresponding to an energy difference between states 242 and 243 impinges on the quantum well, electrons in the quantum well may transition from one split state 243 to the other split state 242 absorbing the photon in the process. The behavior of an electron transition between intervalley states is similar to that of an electron transition between inter subbands except that the former occurs within “one subband.”

Equation 2 provides an approximated valley splitting energy difference Δ in a silicon quantum well:

$$Δ ( F ) \approx 2 \vert \int d \vec{r} exp ( - 2 {iK}_{o} z ) {\vert {ψ}_{0} ( \vec{r} ) \vert}^{2} ( 1.045 V ( \vec{r} ) + \frac{0.414}{{K}_{o}} \frac{\partial V ( \vec{r} )}{\partial z} ) \vert \qquad [ Equation 2 ]$$

where F is an external electric field, Kₒ=0.85×2π/a, a is the silicon lattice constant, ψₒ is the ground state of a single valley, V( r̅)=V_{C}( r̅)+eFz, V_{c} is the confinement potential. Equation 2 was derived assuming that the z-direction lies along the silicon <001> surface.

As can be seen from Equation 2, in the absence of external electric field F, valley splitting corresponds to the confinement potential in the quantum well V_{c}, and its first order derivatives at the interface

$$\frac{\partial {V}_{c} ( \vec{r} )}{\partial z} ,$$

while with a large external electric field, the valley splitting becomes proportional to the external electric field F. Based on the above, the subband energy and valley splitting energy difference Δ while varying the confinement potential, i.e., the width (thickness) of the well and/or the external electric field was calculated.

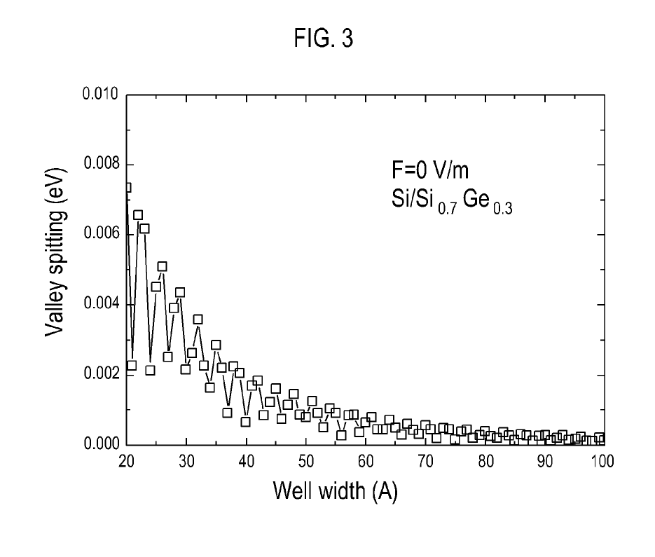

FIG. 3 is an illustrative embodiment of a relationship between valley split energy of a subband and well width of a photodetector having a silicon well layer and silicon germanium barrier layers of the formula Si_{0.7}Ge_{0.3}. In the example of FIG. 3, no external electric field has been applied to the photodetector. In FIG. 3 and FIGS. 4-6 following, the x and y axes represent well width and valley splitting energy, respectively. It can be seen that valley splitting energy difference between intervalley states decreases from about 0.007 eV to 0 eV as the well width increases from 2 nm to 10 nm.

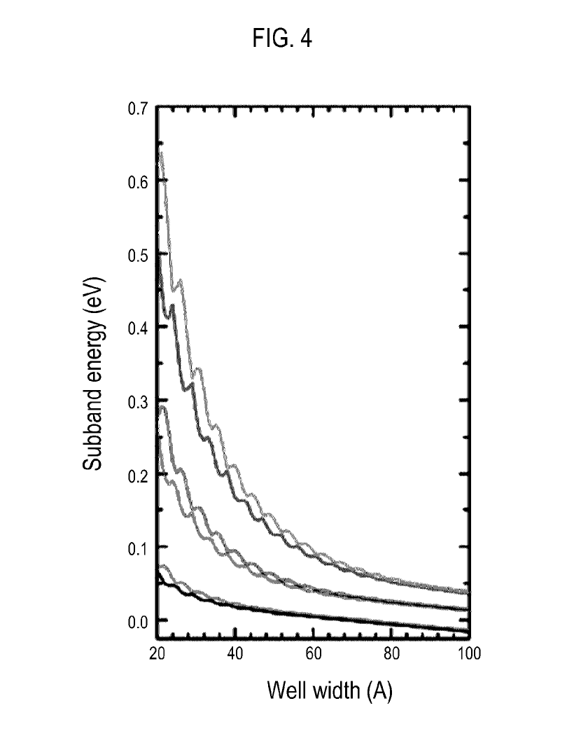

FIG. 4 is an illustrative embodiment of a relationship between valley split energy of multiple subbands and well width of a photodetector having a silicon well layer and silicon dioxide barrier layers. In the example of FIG. 4, a constant external electric field having a magnitude of 1×10⁷ V/m has been applied across the photodetector. It can be seen that the energy difference between intervalley states decreases for three subbands similar as illustrated in FIG. 3 as the well width increases from 2 nm to 10 nm. Compared to FIG. 3, it can be seen that the energy level of each subband and the energy differences between intervalley states of each subband are increased due to the external electric field. For example, the energy level of the lowest subband has a range of about 0.075 eV to 0 eV, and the energy difference between intervalley states of the lowest subband has a range from about 0.025 eV to 0 eV with the well width ranging from 2 nm to 10 nm.

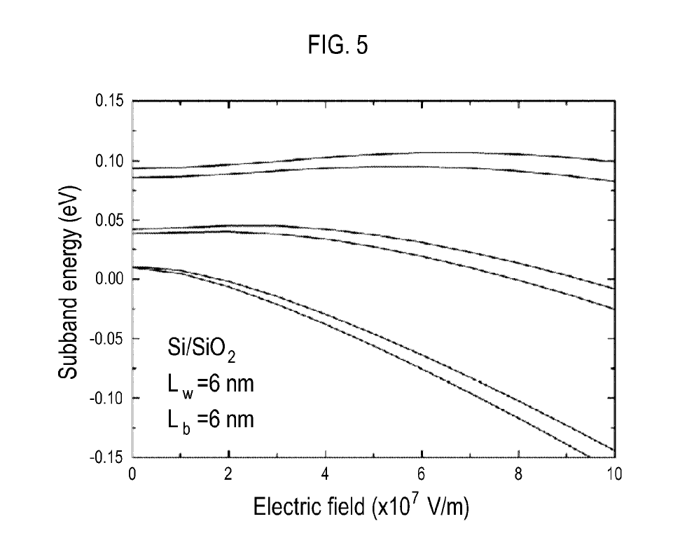

FIG. 5 is an illustrative embodiment of a relationship between multiple subbands energy with valley split and external electric filed of a photodetector having a silicon well layer and silicon dioxide barrier layers. In the example of FIG. 5, a variable external electric field ranging in magnitude from zero to 10×10⁷ V/m has been applied across the photodetector. In this example the quantum well layer has a width of 6 nm. It can be seen that the energy difference between intervalley states increases for three subbands as the external electric field F increases from 0 to 10×10⁷V/m. For example, the energy difference between intervalley states of the lowest subband has range from about 0.005 eV to 0.025 eV with reference to the external electric field of 2×10⁷V/m to 10×10⁷V/m.

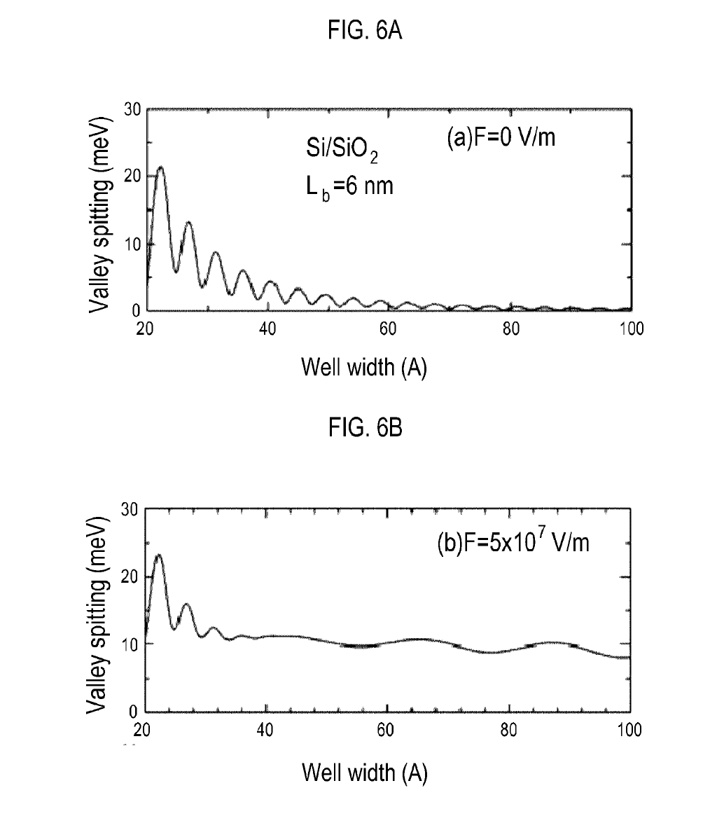

FIGS. 6A to 6C illustrate relationships among valley split energy, well width and external electric field of a photodetector having a silicon well layer and silicon dioxide barrier layers. In examples (a), (b) and (c), the external electric field has magnitudes of 0, 5×10⁷V/m and 10×10⁷V/m, respectively, and the well width has been varied from 2 nm to 10 nm while the barrier layers have 6 nm thickness. It can be seen that the valley splitting in example (a) oscillates and rapidly decreases as the well width increases. While the valley splitting in examples (b) and (c) do not oscillate and decrease as much as in example (a) except for oscillation in the region of 2 nm to 3 nm, as the well width increases. In particular, in example (a), valley splitting decreases from about 10 meV to 0 meV as the well width increases from 2 nm to 10 nm. In example (b), the valley splitting substantially maintains about 10 meV regardless of increasing the well width except for an initial oscillation. In example (c), the valley splitting decreases relatively slowly, i.e., from about 18 meV to 13 meV as the well width increases from 2 nm to 10 nm.

As can be seen from the examples of FIGS. 3-6, valley splitting (energy difference between intervalley states) may be a function of well width in a photodetector and/or a function of external electric field applied to a photodetector. For example, for detecting a photon with an energy of 10 meV to 30 meV, the photodetector may include a silicon well layer having a thickness of 2 nm to 10 nm and may be provided with an external electric field of about 10×10⁷V/m. In another embodiment, for detecting a photon having an energy of 15 meV to 20 meV, the photodetector may include a silicon well layer having a thickness of 2 nm to 10 nm and may be provided with an external electric field of about 5×10⁷V/m. In still another example, for detecting a photon with energy of 5 meV to 10 meV, the photodetector may include a silicon well layer having a thickness of 2 to 3 nm without an external electric field being applied. In the above examples, the barrier layers may include SiO₂ or SiGe and have a thickness similar to the thickness of the well layer.

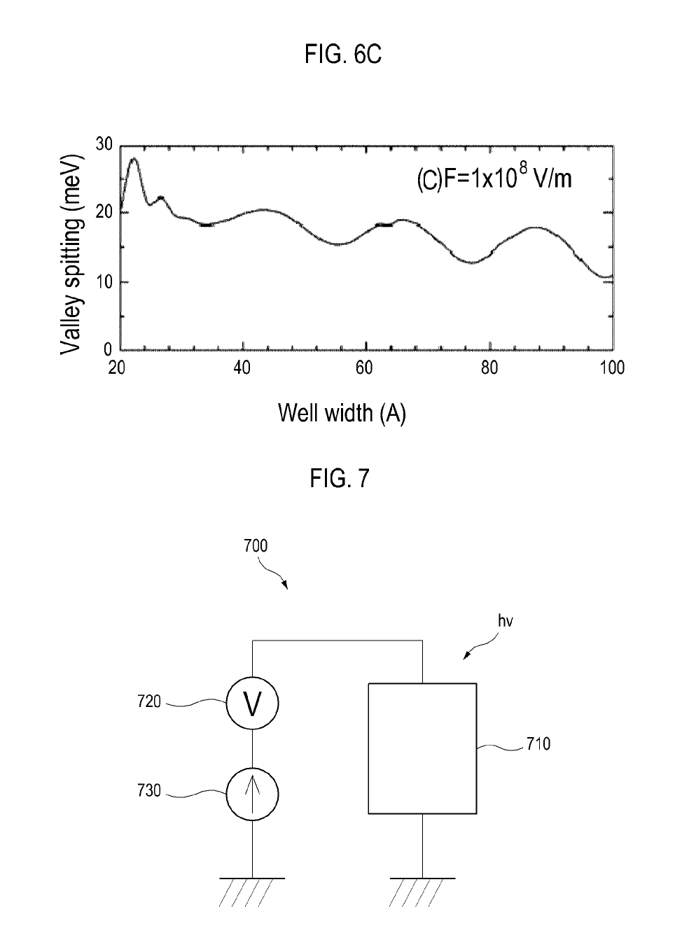

FIG. 7 is a schematic diagram showing an illustrative embodiment of a photodetecting circuit 700. Photodetecting circuit 700 may include a photodetector 710, a voltage source 720 configured to apply an electric field across photodetector 710, and an ammeter 730 to measure an electric current flowing through photodetector 710. Photodetector 710 may include at least one quantum well layer having intervalley states such as photodetector 100 illustrated in FIG. 1.

When voltage source 720 applies a voltage to photodetector 710 forming an electric field across photodetector 710, a quantum structure, such as quantum structure 130 of photodetector 100, in the photodetector may serve as a current cutoff layer and thus current may not flow through photodetector 710. However, to detect photons having an energy ranging from 0 to 30 meV, an electric field across photodetector 710 having a range of 0 to 10×10⁷V/m may be applied causing current to flow through photodetector 710 and be measured by ammeter 730.

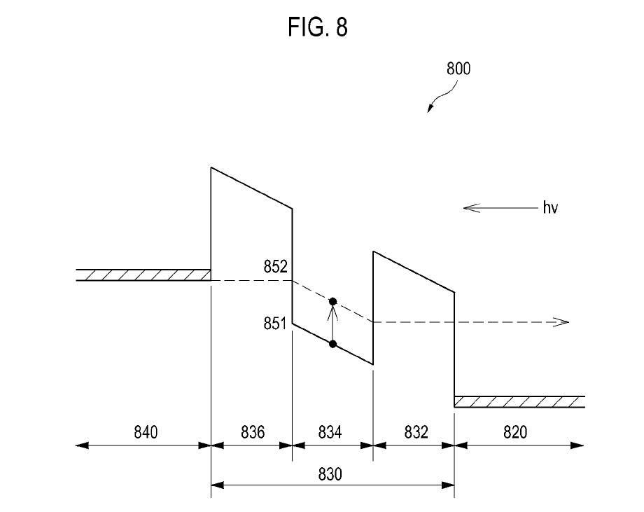

FIG. 8 is an illustrative embodiment of an energy diagram showing a mechanism of photodetection. Reference numerals 820, 830 and 840 represent the regions of a first doped layer, a quantum structure and a second doped layer, respectively, while reference numerals 832, 834 and 836 represent the regions of a first barrier layer, a well layer and a second barrier layer, respectively, in quantum structure 830. Reference numerals 851 and 852 represent a low state and a high state of intervalley state, respectively. Note the embodiment is not limited to those illustrated in the figures, and there may be multiple quantum structures and multiple intervalley states in a well layer.

When no photon impinges on quantum structure 830, electrons are confined in well layer 834 and negligible current flows between doped layers 820 and 840. When a photon, having an energy greater than or equal to the energy difference between intervalley states 851 and 852, impinges on quantum structure 830, electron(s) in low state 851 may be excited to high state 852 and tunnel through barrier layer 820 to generate electric current flowing between doped layers 820 and 840.

Thus, in some embodiments, a photodetector may include a quantum well layer having intervalley states in which electron transitions may permit detection of photons having energy ranging from several to tens of meV energy. The composition and/or structure of the well layer may be varied and/or the magnitude of an applied electric field may be adjusted to yield intervalley states having different energy splittings that may be used to detect photons having corresponding energies.

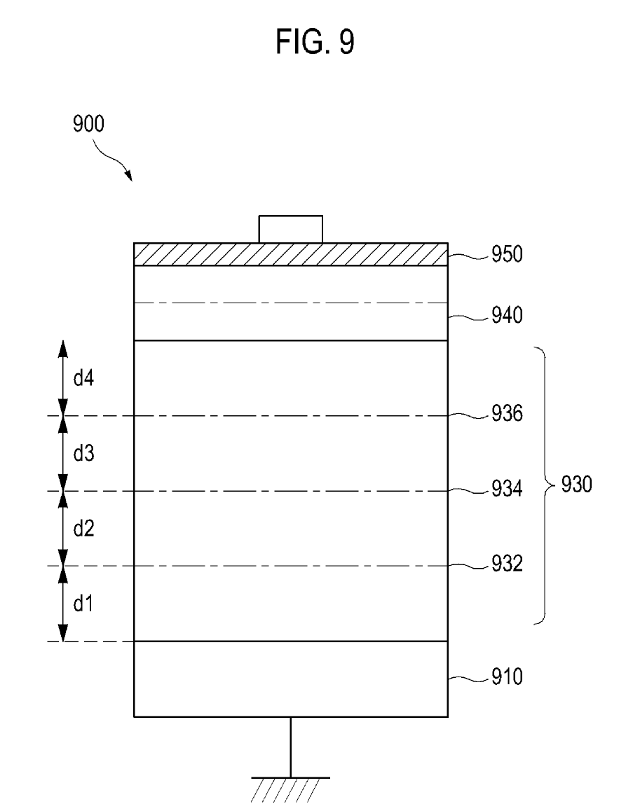

FIG. 9 is a schematic diagram showing another illustrative embodiment of a photodetector 900. In certain embodiments, photodetector 900 may have a laminated structure in which a substrate 910, a quantum well 930, a current injection layer 940, a cap layer 950 and a metal electrode 960 are sequentially stacked. Quantum well 930 may include a first delta-doped layer 932, a second delta-doped layer 934, and a third delta-doped layer 936. Although quantum well 930 includes three delta-doped layers 932, 934 and 936 in FIG. 9, the embodiment is not intended to be limiting in any way. Thus, quantum structure 930 may have one or two delta-doped layers or more than three delta-doped layers. Photodetector 900 may constitute a photodetecting circuit as illustrated in FIG. 7.

Substrate 910 may include semiconductor substrate suitable for growing quantum well 930. For example, substrate 910 may be a Si, SiO₂ or SiGe substrate, etc. when quantum well 930 includes Si. Current injection layer 940 may include highly doped n-type or p-type semiconductor material such as silicon. The n-type impurity may include, for example, at least one of Si, Ge, Sn and Te. The p-type impurity may include, for example, at least one of Zn, Mg, Ca and Be. Cap layer 950 may include highly doped n-type or p-type semiconductor material such as silicon. If current injection layer 940 is n-type doped, cap layer 950 may also n-type doped and vice versa. The doping concentration of cap layer 950 may be higher than that of current injection layer 940 for ohmic contact with metal electrode 960. In certain embodiments, current injection layer 940, cap layer 950 and/or metal electrode 960 may be omitted from photodetector 900.

Delta-doped layers 932, 934 and 936 may have at least one intervalley state of electrons, wherein transition of electrons in the at least one intervalley states may occur in response to a photon having a certain energy. The surface concentrations of delta-doped layers 932, 934, 936 and/or thicknesses d1, d2, d3 and d4 may be varied depending upon the energy of photons to be detected. The predetermined energy difference may have a range from several meV to tens of meV, which corresponds to the energy of a photon having a several THz frequency. For example, the surface concentration of delta-doped layers 932, 934, 936 may be adjusted so that valley splitting energy ranges from 10 to 30 meV, 15 to 20 meV or 5 to 10 meV.

Quantum well 930 may be grown in the form of a single silicon crystal layer formed over substrate 910 to a predetermined thickness d1. Then the growth of quantum well 930 may be temporarily stopped and for example, n type impurity such as Si, Se, Sn or Te may be deposited over well 930 to form first delta-doped layer 932 at a predetermined carrier density. The above mentioned procedures may be repeated twice to form second delta-doped layer 934 and third delta-doped layer 936. Finally, quantum well 930 may be grown over third delta-doped layer 936 to a predetermined thickness d4.

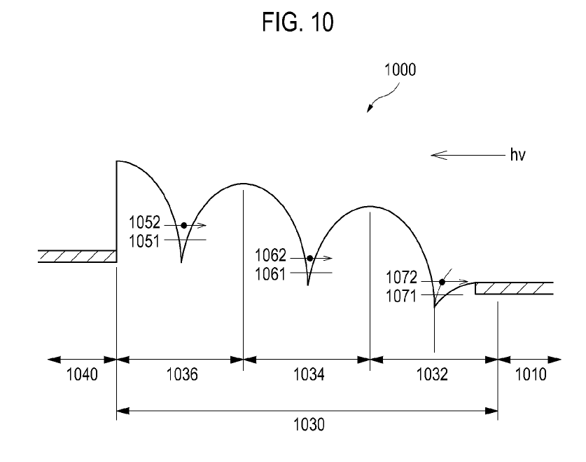

FIG. 10 is an illustrative embodiment of an energy diagram showing a mechanism of photodetection. Reference numerals 1010, 1030 and 1040 represent the regions of a substrate, a quantum well and a current injection layer, respectively. Reference numerals 1032, 1034 and 1036 represent the regions of a first delta-doped layer, a second delta-doped layer and a third delta-doped layer. Reference numerals 1051, 1061 and 1071 represent low states of intervalley states, and 1052, 1062, 1072 represent high states of intervalley states, respectively. Note the above embodiment is not limited to FIG. 10 and there may be more or less quantum wells and multiple in addition to multiple intervalley states within a given well.

When a photon is not impinging on quantum well 1030, electrons remain confined in wells 1032, 1034 and 1036, and thus no current flows. When a photon, which has energy more than or equal to the energy difference between intervalley states 1051 and 1052, 1061 and 1062, or 1071 and 1072 impinges on quantum structure 1030, electron(s) in low states 1051, 1061, 1071 may be excited to high states 1052, 1062, 1072 and tunnel through the barrier to generate electric current.

In some embodiments, a photodetector may include a quantum well layer of delta-doped layer(s) having intervalley states in which electron transitions permit the detection of photons having energies ranging from several to tens of meV.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A photodetector comprising:
a quantum structure; and
a well layer included with the quantum structure,
wherein the well layer is configured to have at least one valley split state of electrons such that one or more transitions of the electrons in the at least one valley split state corresponds to detection of a photon.

2. The photodetector of claim 1, wherein the photon comprises a photon having an energy in a range from several meV to tens of meV.

3. The photodetector of claim 2, wherein the energy comprises a range from 10 meV to 30 meV.

4. The photodetector of claim 1, wherein the well layer comprises silicon.

5. The photodetector of claim 4, wherein the well layer comprises a well layer having a width of 10 nm or less.

6. The photodetector of claim 5, wherein the width comprises from 3 nm to 8 nm.

7. The photodetector of claim 4, wherein the quantum structure comprises at least one barrier layer including silicon.

8. The photodetector of claim 7, wherein the at least one barrier including silicon comprises SiGe or SiO₂.

9. The photodetector of claim 1, further comprising
an electrode configured to apply an electric field across the quantum structure.

10. The photodetector of claim 1, wherein the electric field comprises an electric field ranging from several 10⁷V/m to tens of 10⁷V/m.

11. A photodetector comprising:
a quantum well; and
a delta-doped layer included with the quantum well,
wherein the delta-doped layer includes at least one valley split state of electrons such that a transition of the electrons in the at least one valley split state can occur in response to a photon.

12. The photodetector of claim 11, wherein the photon comprises a photon having an energy ranging from 10 meV to 30 meV.

13. The photodetector of claim 11, wherein the delta-doped layer comprises silicon.

14. A photodetector comprising:
a quantum structure; and
a well layer included with the quantum structure,
wherein the well layer is formed of a material selected from the group consisting of silicon, silicon oxide and silicon germanium, and has a width of 10 nm or less.

15. The photodetector of claim 14, wherein the width is in a range of about 3 nm to about 8 nm.

16. The photodetector of claim 14, wherein the quantum structure comprises at least one barrier layer including silicon.

17. The photodetector of claim 16, wherein at least one barrier comprises at least one of SiGe and SiO₂.

18. The photodetector of claim 14, further comprising
an electrode configured to apply an electric field across the quantum structure.

19. The photodetector of claim 18, wherein the electric field comprises an electric field ranging from several 10⁷V/m to tens of 10⁷V/m.

20. The photodetector of claim 14, wherein the well layer is configured to have at least one valley split state of electrons such that one or more transitions of the electrons in the at least one valley split state corresponds to detection of a photon having an energy in a range from several meV to tens of meV.
